(19) United States
(12) Patent Application Publication
(10) Pub. No.: US 2015/0262917 A1
(43) Pub. Date: Sep. 17, 2015

(54) SEMICONDUCTOR DEVICE AND METHOD OF MANUFACTURING THE SAME

(71) Applicant: KABUSHIKI KAISHA TOSHIBA, Tokyo (JP)

(72) Inventor: Takeshi FUKUI, Hyogo Himeji (JP)

(21) Appl. No.: 14/446,204

(22) Filed: Jul. 29, 2014

(30) Foreign Application Priority Data
Mar. 12, 2014 (JP) 2014-049436

(51) Int. Cl. H01L 23/495; H01L 21/56; H01L 23/00; H01L 23/29; H01L 21/48

(52) U.S. Cl. CPC H01L 23/49524; H01L 23/293; H01L 23/49541; H01L 21/4842; H01L 23/49568; H01L 24/27; H01L 24/83; H01L 24/32; H01L 21/56; H01L 2224/3226; H01L 2224/8385; H01L 2924/07025; H01L 2924/0695; H01L 2924/01014; H01L 2924/01029; H01L 2924/01028; H01L 2924/01047; H01L 2924/01079; H01L 2924/01013

(57) ABSTRACT

A semiconductor device includes a semiconductor chip, a metallic lead frame, a metallic connector, and a sealing portion. The semiconductor chip includes a front surface electrode. The lead frame includes a first portion with a front surface on which the semiconductor chip is mounted, and a second portion which is physically separate from the first portion. The connector includes a first joining portion which is joined to the front surface of the semiconductor chip, a second joining portion which extends perpendicularly with respect to and is joined to a front surface of the second portion, and a connection portion which connects the first joining portion and the second joining portion. The sealing portion covers the semiconductor chip, the front surfaces of the first and second portions, and the metallic connector.

### CROSS-REFERENCE TO RELATED APPLICATION

This application is based upon and claims the benefit of priority from Japanese Patent Application No. 2014-049436, filed Mar. 12, 2014, the entire contents of which are incorporated herein by reference.

### BACKGROUND

In a semiconductor device according to the related art in which a semiconductor chip and a lead frame are electrically connected by a connector, at the time of joining the connector by a solder reflow process, a position shift or inclination of the connector occurs due to buoyancy of the melted solder. The position shift or inclination of the connector may cause generation of cracks, a reduction in yield, a separation between the connector and a resin, a degradation in reliability, or the like.

Also, in the semiconductor device according to the related art, the semiconductor chip, and a connection terminal (a wire or the connector) connecting the semiconductor chip and the lead frame are entirely covered with an insulating resin. In such a semiconductor device, it is difficult to dissipate heat generated by the semiconductor chip because heat radiation has to be performed through the resin which has a thermal conductivity lower than those of metals. For example, in a semiconductor device in which a large amount of current flows during operation, such as an in-vehicle or industrial semiconductor device, a problem arises when there is a large amount of heat generated by the semiconductor chip that cannot be dissipated adequately.

### DESCRIPTION OF THE DRAWINGS

FIGS. 1A and 1B are views schematically illustrating the configuration of a semiconductor device according to a first embodiment.

FIGS. 2A and 2B are views schematically illustrating the configuration of another example of the semiconductor device according to the first embodiment.

FIGS. 3A and 3B are views schematically illustrating the configuration of another example of the semiconductor device according to the first embodiment.

FIGS. 4A and 4B are views schematically illustrating the configuration of another example of the semiconductor device according to the first embodiment.

FIGS. 5A and 5B are views schematically illustrating the configuration of another example of the semiconductor device according to the first embodiment.

FIGS. 6A to 6D are explanatory views illustrating a process of manufacturing the semiconductor device according to the first embodiment.

FIGS. 7A and 7B are views schematically illustrating the configuration of a semiconductor device according to a second embodiment.

FIGS. 8A and 8B are views schematically illustrating a semiconductor device according to a third embodiment.

### DETAILED DESCRIPTION

Embodiments provide a semiconductor device capable of improving reliability and reducing on-resistance.

In general, according to one embodiment, a semiconductor device includes a semiconductor chip, a metallic lead frame, a metallic connector, and a sealing portion. The semiconductor chip includes a front surface electrode. The lead frame includes a first portion with a front surface on which the semiconductor chip is mounted, and a second portion which is physically separate from the first portion. The connector includes a first joining portion which is joined to the front surface of the semiconductor chip, a second joining portion which extends perpendicularly with respect to and is joined to a front surface of the second portion, and a connection portion which connects the first joining portion and the second joining portion. The sealing portion covers the semiconductor chip, the front surfaces of the first and second portions, and the metallic connector.

Hereinafter, semiconductor devices according to embodiments and a method of manufacturing a semiconductor device according to embodiments will be described with reference to the accompanying drawings.

### First Embodiment

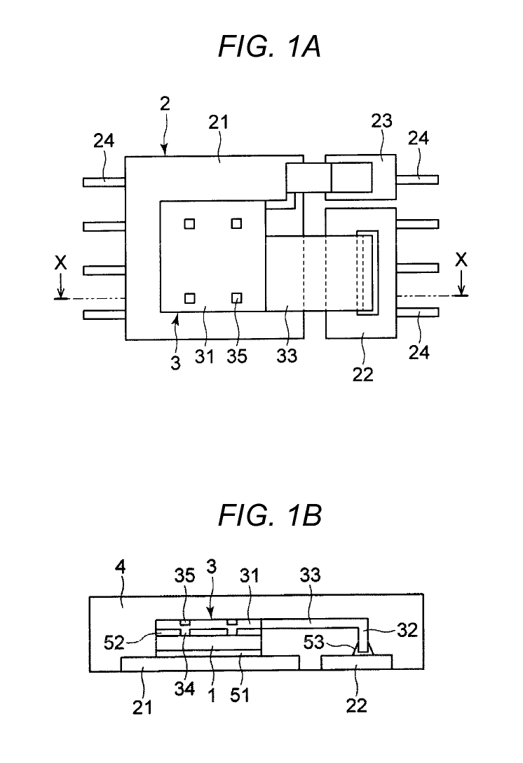

First, a semiconductor device according to a first embodiment will be described with reference to FIGS. 1A to 5B. In the semiconductor device according to the present embodiment, a semiconductor chip 1 and a lead frame 2 are electrically connected by a connector 3, and the semiconductor chip 1 is sealed with a sealing portion 4 made of a resin.

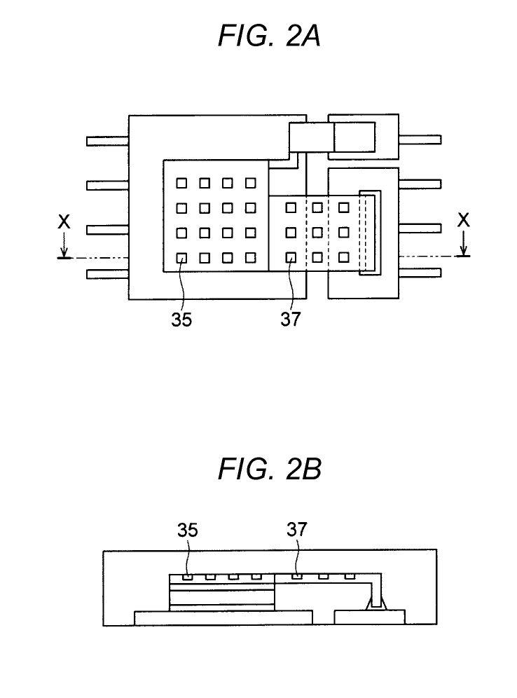

Here, FIG. 1A is a plan view illustrating the semiconductor device according to the present embodiment. In FIG. 1A, the sealing portion 4 sealing the semiconductor chip 1 is not shown. Also, FIG. 1B is a cross-sectional view taken along line X-X of FIG. 1A. In FIG. 1B, the sealing portion 4 sealing the semiconductor chip 1 is illustrated. Similarly, in plan views of FIGS. 2A to 8A, the sealing portion 4 is not illustrated, and in cross-sectional views of FIGS. 2B to 8B, the sealing portion 4 is illustrated. As illustrated in FIGS. 1A and 1B, the semiconductor device according to the present embodiment includes the semiconductor chip 1, the lead frame 2, the connector 3, the sealing portion 4, and joining portions 51, 52, and 53.

The semiconductor chip 1 may include therein an insulated gate bipolar transistor (IGBT), a power metal oxide semiconductor (MOS) transistor, a power integrated circuit (IC), and the like, and includes electrodes which are formed on the front surface and the rear surface to drive the transistor, the circuit, or the like described above. An electrode (hereinafter, referred to as a front surface electrode) which is formed on the front surface of the semiconductor chip 1 is provided on the entire or part of the front surface of the semiconductor chip 1. The front surface electrode is connected, for example, to a high-voltage power source. An electrode (hereinafter, referred to as a rear surface electrode) which is formed on the rear surface of the semiconductor chip 1 is provided on the entire or part of the rear surface of the semiconductor chip 1. The rear surface electrode is connected, for example, to a low-voltage power source. Also, in this description, a front surface represents an upper surface in a cross-sectional view, and a rear surface represents a lower surface in a cross-sectional view. The semiconductor chip 1 is joined to a bed portion 21 of the lead frame 2.

The lead frame 2 is a plate-shaped metal member to which the semiconductor chip 1 is fixed, and includes the bed portion 21 and post portions 22 and 23. As illustrated in FIG. 1A, the bed portion 21 and the post portions 22, 23 have outer leads 24 for connecting the semiconductor chip 1 to external wiring lines. Also, as illustrated in FIG. 1B, the rear surface of the bed portion 21 of the lead frame 2 is exposed and not covered by the sealing portion 4.

On the front surface of the bed portion 21 (a first portion), the semiconductor chip 1 is mounted. The semiconductor chip 1 is joined to the front surface of the bed portion 21 by the joining portion 51. The joining portion 51 is formed of an electrically conductive adhesive, for example, solder or an electrically conductive resin containing silver. The front surface of the bed portion 21 and the rear surface of the semiconductor chip 1 are joined by the electrically conductive joining portion 51, whereby the bed portion 21 and the rear surface electrode of the semiconductor chip 1 are electrically connected. As a result, the external wiring lines (for example, of the low-voltage power source) connected to the outer leads 24 of the bed portion 21 are electrically connected to the rear surface of the semiconductor chip 1.

As described above, the bed portion 21 is formed of a metal and thus has thermal conductivity higher than those of resins. Also, the rear surface of the bed portion 21 is exposed and not covered by the sealing portion 4. The semiconductor device according to the present embodiment may radiate heat generated by the semiconductor chip 1, through the bed portion 21 configured as described above. Therefore, it is possible to improve the heat dissipation properties of the semiconductor device.

The post portion 22 (a second portion) is electrically connected to the front surface electrode of the semiconductor chip 1 through the connector 3. The post portion 22 is connected to external wiring lines through outer leads 24. The post portion 22 is provided apart from the bed portion 21.

The post portion 23 is electrically connected to a control electrode of the semiconductor chip 1. The control electrode of the semiconductor chip 1 is electrically connected to the post portion 23, thereby being electrically connected to an external wiring line (for example, to a control circuit) connected to the outer lead 24 of the post portion 23. The control electrode of the semiconductor chip 1 and the post portion 23 are electrically connected by an arbitrary connection terminal such as a wire or a connector. The post portion 23 is provided apart from the bed portion 21 and the post portion 22.

Also, the bed portion 21 and the post portions 22 and 23 need to be insulated from each other, and for example, gaps between the bed portion 21 and the post portions 22 and 23 may be filled with an insulating resin.

The connector 3 is a plate-shaped metal member for electrically connecting the front surface electrode of the semiconductor chip 1 and the post portion 22. The connector 3 electrically connects the front surface electrode of the semiconductor chip 1 and the post portion 22, whereby the front surface electrode of the semiconductor chip 1 and external wiring lines (for example, of the high-voltage power source) are electrically connected through the outer leads 24 of the post portion 22.

The connector 3 is formed of a metal material such as copper, copper plated with nickel, copper plated with silver, copper plated with gold, a copper alloy, or aluminum. Therefore, the connector 3 exhibits a superior and low on-resistance characteristic, and exhibits high adhesion with respect to an adhesive, as compared to a wire. The connector 3 includes a chip joining portion 31, a post joining portion 32, and a connection portion 33.

The rear surface of the chip joining portion 31 (a first joining portion) is joined to the front surface of the semiconductor chip 1 by the joining portion 52. The joining portion 52 is formed of an electrically conductive adhesive, for example, solder or an electrically conductive resin material containing silver. The chip joining portion 31 and the front surface of the semiconductor chip 1 are joined by the electrically conductive joining portion 52. As a result, the chip joining portion 31 and the front surface electrode of the semiconductor chip 1 are electrically connected.

As illustrated in FIGS. 1A and 1B, the chip joining portion 31 has a flat plate shape, and is disposed to cover the entire or part of the front surface of the semiconductor chip 1, and includes a plurality of protruding portions 34 formed on a rear surface thereof, that is, a surface thereof to be joined with the semiconductor chip 1. The protruding portions 34 are formed by pressing, such as half punching, and are rectangular as seen in the plan view. It is preferable that at least some of the plurality of protruding portions 34 are not disposed in parallel with an X direction (a direction along the line X-X of FIG. 1A) and a Y direction (a direction perpendicular to the line X-X of FIG. 1A). If the protruding portions 34 are disposed as described above, the protruding portions 34 acts to hold the semiconductor chip 1 down during melting of the adhesive in a reflow process (to be described below), whereby variation in height of the joining portion 52 may be suppressed. Therefore, it is possible to prevent the connector 3 from being obliquely joined to the semiconductor chip 1.

In FIGS. 1A and 1B, it is preferable that the ratio of the total area of the protruding portions 34 to the area of the joining surface is equal to or less than a predetermined value. This is because if the ratio is larger than the predetermined value, generation of voids or an increase in stress attributable to the protruding portions 34 may result in problems such as an increase in on-resistance, or a reduction in joint strength and reliability. In order to avoid those problems, the ratio is set to, for example, 5% or less. Also, the number, shapes, and layout of the protruding portions 34 may be arbitrarily set.

Also, at the front surface of the chip joining portion 31, at least one recess 35 is formed. In FIGS. 1A and 1B, the protruding portions 34 are formed on the rear surface of the chip joining portion 31, whereby the recesses 35 are formed in the front surface opposite to the protruding portions 34. If the recesses 35 are formed in the front surface of the chip joining portion 31, the adhesion strength between the chip joining portion 31 and the sealing portion 4 is improved due to an anchoring effect. Therefore, during a thermal process such as a reflow process, it is possible to suppress separation between the chip joining portion 31 and the sealing portion 4, and to reduce stress on the joining portion 52.

Also, the recesses 35 may be formed integrally with the protruding portions 34 as illustrated in FIGS. 1A and 1B by pressing, or may be formed separately from the protruding portions 34 as illustrated in FIGS. 2A and 2B. Recesses 35 as illustrated in FIGS. 2A and 2B may be formed, for example, by laser machining or the like.

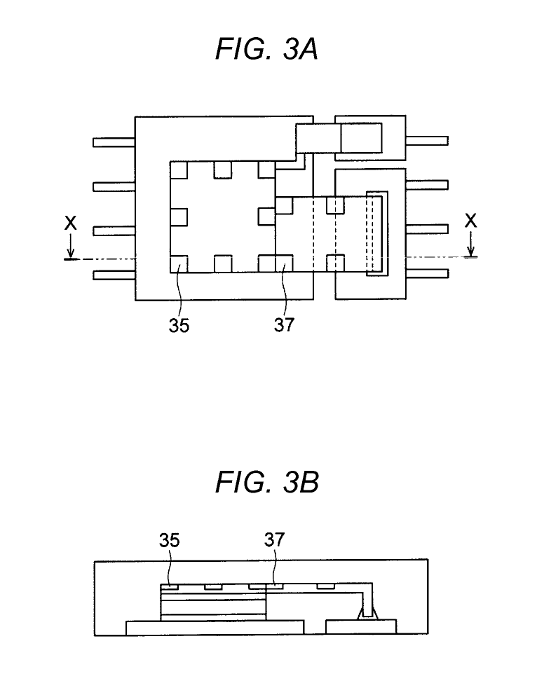

Also, the recesses 35 may be formed at the outer peripheral portion of the chip joining portion 31 as illustrated in FIGS. 3A and 3B by cutout.

It is possible to arbitrarily set the number, shapes, and layout of recesses 35. In addition, it is preferable to form the protruding portions 34 and the recesses 35 such that the area of the front surface of the chip joining portion 31 is larger than the area of the rear surface. Then, it is possible to improve the adhesion strength between the chip joining portion 31 and the sealing portion 4.

The post joining portion 32 (a second joining portion) is joined to the front surface of the post portion 22 of the lead frame 2 by the joining portion 53. The joining portion 53 is formed of an electrically conductive adhesive, for example, solder or an electrically conductive resin material containing silver. The post joining portion 32 and the post portion 22 are joined by the electrically conductive joining portion 53, whereby the post joining portion 32 and the post portion 22 are electrically connected.

The post joining portion 32 is formed in a flat plate shape perpendicular to the chip joining portion 31. That is, the post joining portion 32 is a plate-shaped portion of the connector 3 integrally formed of a metal, being bent from the connection portion 33 toward the post portion 22. An end of the post joining portion 32 on the post portion 22 side is joined to the post portion 22, whereby the post joining portion 32 is joined perpendicularly to the post portion 22. According to this configuration, when the post joining portion 32 is joined to the post portion 22, the buoyancy of a melted adhesive on the post joining portion 32 decreases. Therefore, it is possible to suppress variations in thickness of the joining portion 53, to prevent the connector 3 from being obliquely joined, and to prevent the position of the post joining portion 32 from being shifted due to the buoyancy of the melted adhesive.

Also, since the melted adhesive creeps up the side surfaces of the post joining portion 32, thereby forming fillets, it is possible to sufficiently secure the adhesion strength between the post joining portion 32 and the post portion 22, and to prevent generation of cracks or the like attributable to stress. In the present embodiment, it is preferable that the height of each fillet of the joining portion 53 is equal to or larger than a third of the height of the post joining portion 32 such that the adhesion strength between the post joining portion 32 and the post portion 22 is sufficiently secured.

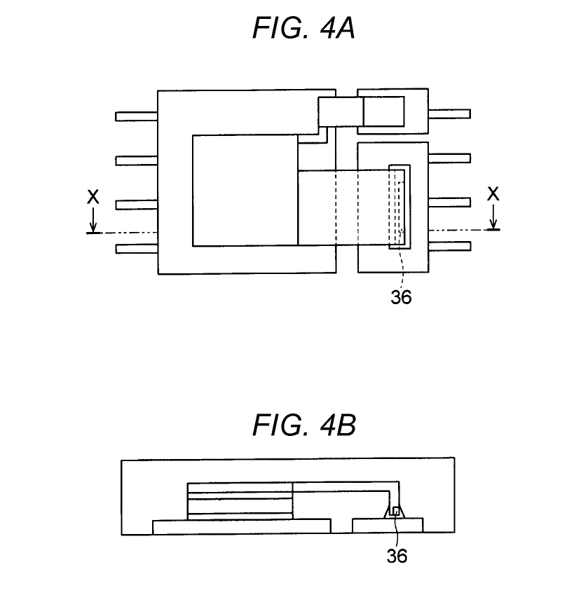

Also, it is preferable that the post joining portion 32 is provided with a recess 36 formed at least a portion of the side surfaces of the lower end to be joined to the post portion 22 as illustrated in FIGS. 4A and 4B. The recess 36 may be formed by cutout or the like. The length and height of the recess 36 may be arbitrarily set. For example, the recess 36 may be formed such that the length becomes a third of the length of the lower end of the post joining portion 32, and the height becomes a third of the height of the post joining portion 32. According to this configuration, when the post joining portion 32 is joined to the post portion 22, the buoyancy of the melted adhesive further decreases. Therefore, it is possible to suppress inclination of the connector 3 and position shift of the post joining portion 32. Also, the melted adhesive enters the recess 36, and the area of the joining portion 53 in a horizontal direction decreases. Therefore, it is possible to reduce stress on the joining portion 53.

The connection portion 33 is a portion connecting the chip joining portion 31 and the post joining portion 32. The connection portion 33 may be formed in an arbitrary shape capable of connecting the chip joining portion 31 and the post joining portion 32, and may be formed in a flat plate shape parallel to the chip joining portion 31 as illustrated in FIGS. 1A and 1B.

Also, it is preferable that at least one recess 37 is formed in the front surface of the connection portion 33 as illustrated in FIGS. 2A, 2B, 3A, 3B, 5A, and 5B. If the recess 37 is formed in the front surface of the connection portion 33, the adhesion strength between the connection portion 33 and the sealing portion 4 is improved due to the anchoring effect. Therefore, during a thermal process such as a reflow process, it is possible to suppress separation between the connection portion 33 and the sealing portion 4.

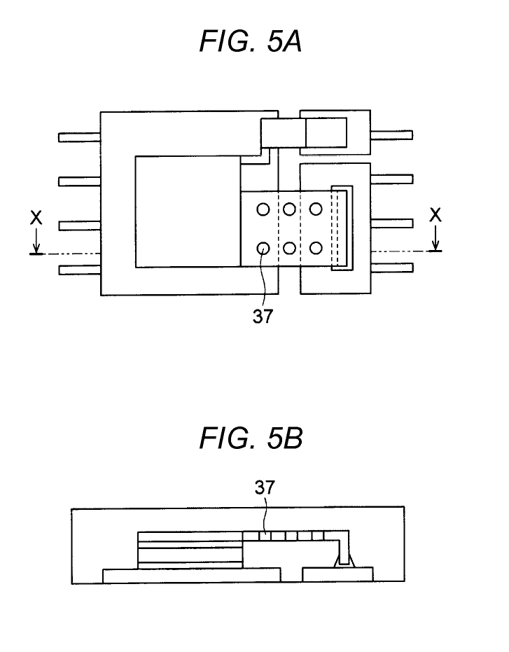

The recess 37 may be formed in the front surface of the connection portion 33 as illustrated in FIGS. 2A and 2B by laser machining, or may be formed in the outer peripheral portion of the front surface of the connection portion 33 as illustrated in FIGS. 3A and 3B by cutout. Also, the recess 37 may be formed through the connection portion 33 from the front surface to the rear surface as illustrated in FIGS. 5A and 5B by punching. It is possible to arbitrarily set the number, shapes, and layout of recesses 37.

The sealing portion 4 is formed to cover the entire semiconductor chip 1, thereby constituting the case of the semiconductor device while protecting the semiconductor chip 1 from an external force and air. The sealing portion 4 is formed of an insulating resin such that the lead frame 2 is exposed at its rear surface and the outer leads 24 protrude from side surfaces thereof.

As described above, in the semiconductor device according to the present embodiment, since the post joining portion 32 having a flat plate shape is joined perpendicularly to the post portion 22, during melting of the adhesive, the buoyancy of the adhesive on the post joining portion 32 decreases. As a result, the joining portion 53 is formed in a uniform thickness, whereby inclination of the connector 3 is suppressed, and position shift of the post joining portion 32 is also suppressed. As described above, a degradation in reliability attributable to inclination or position shift of the connector 3 is suppressed. Therefore, the semiconductor device according to the present embodiment has high reliability.

Also, in the semiconductor device according to the present embodiment, heat generated by the semiconductor chip 1 is radiated through the bed portion 21 of the lead frame 2. The bed portion 21 is formed of a metal having high thermal conductivity, and the rear surface of the bed portion 21 is exposed and not covered by the sealing portion 4. Therefore, the semiconductor device according to the present embodiment has high heat dissipating properties. According to this configuration, the semiconductor device according to the present embodiment may be appropriately used as a power module having an IGBT, a power MOS transistor, a power IC, and the like which are required to have high heat dissipating properties.

Also, the semiconductor device may include a plurality of semiconductor chips. For example, the present embodiment may be applied to an inverter or the like which includes a high-voltage side semiconductor chip and a low-voltage side semiconductor chip and in which the two semiconductor chips are connected through a connector 3.

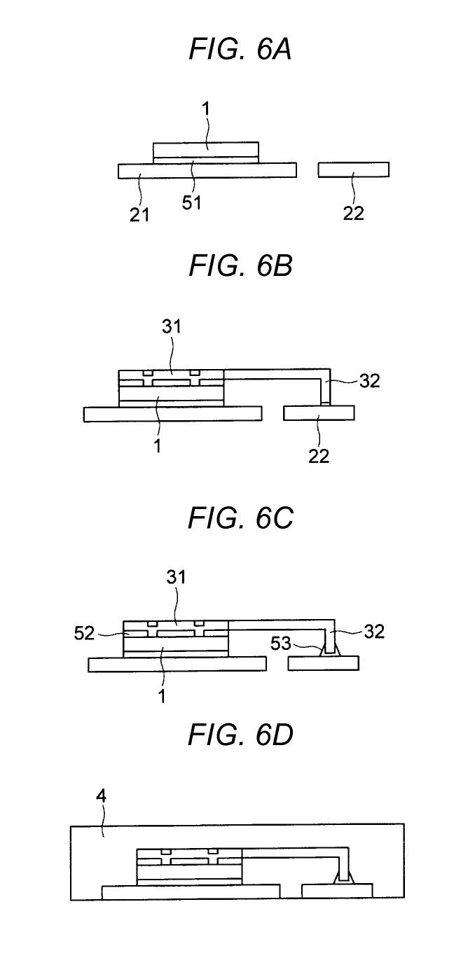

Subsequently, a method of manufacturing the semiconductor device according to the present embodiment will be described with reference to FIGS. 6A to 6D. Here, FIGS. 6A to 6D are explanatory views illustrating the method of manufacturing the semiconductor device according to the present embodiment, and are cross-sectional views illustrating the semiconductor device in individual processes.

First, an adhesive, such as a solder paste or a resin paste, such as a resin paste containing silver, is applied to a predetermined position of the front surface of the bed portion 21 of the lead frame 2, and the semiconductor chip 1 is mounted on the corresponding adhesive. Next, the semiconductor chip 1 is joined to the bed portion 21 by a reflow process. That is, in a state where the semiconductor chip 1 has been mounted, heating is performed, whereby the adhesive is melted, and then cooling is performed, whereby the adhesive is coagulated. As a result, the joining portion 51 is formed, such that the semiconductor chip 1 is joined to the front surface of the bed portion 21 by the joining portion 51 (see FIG. 6A).

Next, an adhesive, such as a solder paste or a resin paste, such as a resin paste containing silver, is applied to a predetermined position of the front surface of the semiconductor chip 1 and a predetermined position of the front surface of the post portion 22 of the lead frame 2, and the connector 3 is mounted on the corresponding adhesive (see FIG. 6B). Thereafter, the connector 3 is joined by a ref low process. That is, in a state where the connector 3 has been mounted, heating is performed, whereby the adhesive is melted, and then cooling is performed, whereby the adhesive is coagulated. As a result, the joining portions 52 and 53 are formed, such that the post joining portion 32 is joined to the post portion 22 by the joining portion 52 and the chip joining portion 31 is joined to the front surface of the semiconductor chip 1 by the joining portion 53 (see FIG. 6C). In this case, it is preferable that in the joining portion 53, fillets having heights equal to or larger than a third of the height of the post joining portion 32 are formed.

Next, the semiconductor device in the state of FIG. 6C is introduced into a mold, and a resin is molded. That is, the entire semiconductor chip 1 is covered and sealed with an insulating resin (see FIG. 6D). In FIG. 6D, the entire connector 3, and the bed portion 21 and the post portions 22 and 23 of the lead frame 2 are covered with the sealing portion 4, and the outer leads 24 of the lead frame 2 are exposed from the side surfaces of the sealing portion 4.

The rear surface of the sealing portion 4 formed as described above is polished by a chemical mechanical polishing (CMP) method, whereby the semiconductor device according to the present embodiment and shown in FIGS. 1A and 1B is manufactured. The rear surface of the sealing portion 4 is polished until at least a portion of the rear surface of the bed portion 21 of the lead frame 2 is exposed.

As described above, after the resin is molded, the rear surface of the sealing portion 4 is polished, whereby it is possible to planarize the sealing portion 4, thereby reducing stress on the front surface side and the rear surface side of the sealing portion 4. Therefore, it is possible to improve the reliability of the semiconductor device. Also, the front surface of the sealing portion 4 may be polished such that the sealing portion 4 is planarized.

As described above, according to the method of manufacturing the semiconductor device according to the present embodiment, after the post joining portion 32, having a flat plate shape, is mounted perpendicularly on the post portion 22, and the adhesive is melted by the reflow process, the post joining portion 32 is joined to the post portion 22. Therefore, it is possible to reduce the buoyancy of the adhesive on the post joining portion 32 during melting of the adhesive in the reflow process. Therefore, it is possible to suppress inclination and position shift of the connector 3 attributable to the melted adhesive, and to improve the reliability of the semiconductor device.

Also, in the method of manufacturing the semiconductor device according to the present embodiment, it is possible to omit the reflow process after the adhesive is applied to the bed portion 21 of the lead frame 2, and to perform the corresponding reflow process collectively with the reflow process for joining the connector 3.

Also, in the method of manufacturing the semiconductor device according to the present embodiment, it is possible to mold the resin such that the rear surface of the lead frame 2 is not covered with the sealing portion 4. According to this configuration, it is possible to omit or simplify the above described polishing process.

### Second Embodiment

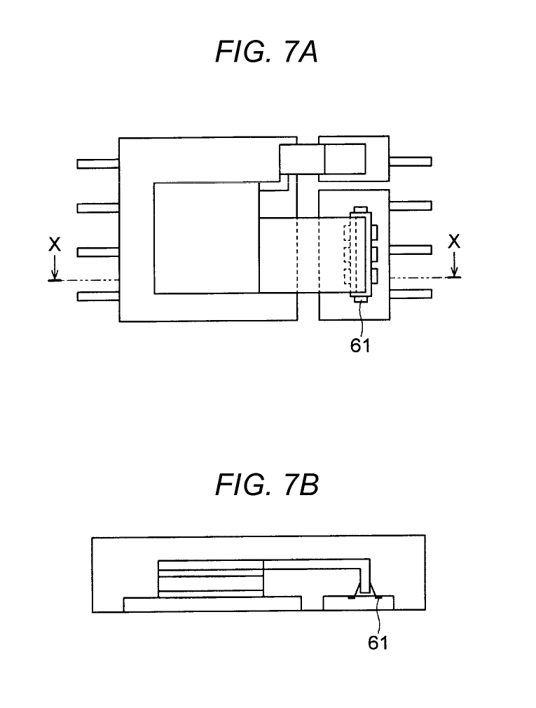

Subsequently, a semiconductor device according to a second embodiment will be described with reference to FIGS. 7A and 7B. In the semiconductor device according to the second embodiment, wetting preventing portions 61 are formed to surround the joint surfaces of the post portion 22 of the lead frame 2 and the post joining portion 32 of the connector 3. The other configurations and the method of manufacturing the semiconductor device according to the second embodiment are the same as those of the first embodiment, and thus will not be described.

The wetting preventing portions 61 are portions processed such that the wettability of the melted adhesive becomes worse (a contact angle decreases), and may be formed, for example, by processing the front surface of the post portion 22 of the lead frame 2 with a laser. Oxide films formed at the portions machined with the laser have wettability lower than that of the surrounding portion, and thus function as the wetting preventing portions 61.

The wetting preventing portions 61 are formed at a predetermined interval so as to be apart from the joint surfaces by 50 μm or more and surround the joint surfaces. The length, layout, and the like of the wetting preventing portions 61 may be arbitrary selected according to the voltage characteristics and areas of the joint surfaces.

According to the present embodiment, during the reflow process for joining the post portion 22 and the post joining portion 32, flows of the melted adhesive toward the outer sides of the joined surfaces are suppressed. Therefore, it is possible to obtain the proper amount of adhesive for joining the post joining portion 32 to the post portion 22. Therefore, it is possible to suppress a degradation in reliability of the semiconductor device attributable to the amount of adhesive.

### Third Embodiment

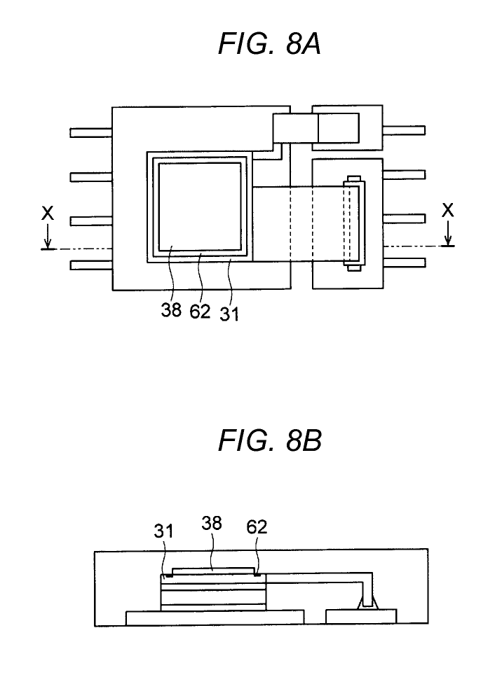

A semiconductor device according to a third embodiment will be described with reference to FIGS. 8A and 8B. The semiconductor device according to the third embodiment includes an insulating portion 38 formed of an encapsulating material on a portion of the front surface of the chip joining portion 31 of the connector 3. The other configurations and the method of manufacturing the semiconductor device according to the third embodiment are the same as those of the first embodiment, and thus will not be described.

The insulating portion 38 is formed by applying the encapsulating material on the front surface of the chip joining portion 31. The encapsulating material can include materials, such as at least one of a thermosetting silicon gel, polyimide, or polyamide. On the front surface of the chip joining portion 31, the encapsulating material flows, whereby wetting preventing portions 62 are formed so as not to cover the semiconductor chip 1 and so as to surround the circumference of the insulating portion 38. Alternatively, half punching is performed on the front surface of the chip joining portion 31, whereby a recess is formed to surround the circumference of the insulating portion 38.

According to the third embodiment having the above described configuration, the insulating portion 38 is formed on the front surface of the chip joining portion 31. Therefore, it is possible to improve the humidity resistance of the chip joining portion 31, to improve the adhesion strength between the chip joining portion 31 and the sealing portion 4, and to prevent the sealing portion 4 from peeling off from the connector 3 during a thermal process, such as a ref low process. Also, the insulating portion 38 is configured so as not to cover the semiconductor chip 1. Therefore, it is possible to prevent a slide of an aluminum electrode (an Al slide) during an operation of the semiconductor device and during a high or low temperature cycle.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor chip that includes a front surface electrode;
a metallic lead frame including a first portion with a front surface on which the semiconductor chip is mounted, and a second portion which is physically separate from the first portion;
a metallic connector including a first joining portion which is joined to a front surface of the semiconductor chip, a second joining portion which extends perpendicularly with respect to and is joined to a front surface of the second portion, and a connection portion which connects the first joining portion and the second joining portion; and
a sealing portion that covers the semiconductor chip, the front surfaces of the first and second portions, and the metallic connector.

2. The semiconductor device according to claim 1, wherein
rear surfaces of the first and second portions are exposed and not covered by the sealing portion.

3. The semiconductor device according to claim 1, wherein
the connector has a flat plate shape and the second joining portion is bent from the connection portion toward the second portion, and
an end of the second joining portion on the second portion side is joined to the second portion, so that the second joining portion is joined to the second portion perpendicularly.

4. The semiconductor device according to claim 1, further comprising:
wetting preventing portions on the front surface of the second portion that surround joint surfaces of the second portion and the second joining portion to suppress wetting by an adhesive.

5. The semiconductor device according to claim 4, wherein
the wetting preventing portions include oxide films.

6. The semiconductor device according to claim 1, wherein
the first joining portion includes a plurality of protruding portions on a rear surface thereof.

7. The semiconductor device according to claim 6, wherein
the first joining portion includes at least one recess on a front surface thereof.

8. The semiconductor device according to claim 7, wherein
each recess on the front surface of the first joining portion has a corresponding protruding portion on the rear surface of the first joining portion and is located opposite to the corresponding protruding portion on the rear surface of the first joining portion.

9. The semiconductor device according to claim 1, wherein
the second joining portion has a lower end that is joined to the second portion, and a recess in at least a portion of one or more side surfaces of the lower end.

10. The semiconductor device according to claim 1, further comprising:
fillets of an adhesive material surrounding side surfaces of the second joining portion and having heights equal to or larger than a third of a height of the second joining portion.

11. The semiconductor device according to claim 1, further comprising:
an insulating portion containing at least one of silicon, polyimide, and polyamide, on at least a portion of the front surface of the first joining portion.

12. The semiconductor device according to claim 1, wherein
the connector is made of one of copper, copper plated with nickel, copper plated with silver, copper plated with gold, a copper alloy, and aluminum.

13. A method of manufacturing a semiconductor device comprising:
joining a semiconductor chip including a front surface electrode, to a front surface of a first portion of a metallic lead frame;
applying an adhesive on a front surface of the semiconductor chip, and a front surface of a second portion of the lead frame that is physically separate from the first portion;
joining a metallic connector including a first joining portion, a second joining portion, and a connection portion that connects the first joining portion and the second joining portion, to the semiconductor chip and the second portion, with the adhesive, the first joining portion being joined to the front surface of the semiconductor chip, and the second joining portion extending perpendicularly with respect to and being joined to a front surface of the second portion; and
sealing the semiconductor chip, the connector, and the front surfaces of the first and second portion with a resin.

14. The method of claim 13, wherein after said sealing, rear surfaces of the first and second portions are exposed and not covered by the resin.

15. The method of claim 13, wherein after said sealing, polishing so that the rear surfaces of the first and second portions become exposed.

16. The method of claim 13, further comprising:
bending a portion of the metallic connector to form the second joining portion.

17. The method of claim 13, further comprising:
forming a plurality of protruding portions on a rear surface of the first joining portion.

18. The method of claim 17, wherein, after said joining, the protruding portions are in direct contact with the front surface of the semiconductor chip and a ratio of a total area of the protruding portions that are in direct contact with the front surface of the semiconductor chip to a total surface area of the front surface of the semiconductor chip is 5% or less.

19. The method of claim 17, further comprising:
forming at least one recess on the front surface of the first joining portion.

20. The method of claim 19, wherein
each recess on the front surface of the first joining portion has a corresponding protruding portion on the rear surface of the first joining portion and is located opposite to the corresponding protruding portion on the rear surface of the first joining portion.
